(19) United States
(12) Patent Application Publication
(10) Pub. No.: US 2014/0345693 A1
(43) Pub. Date: Nov. 27, 2014

(54) PHOTOELECTRIC CONVERSION DEVICE AND METHOD FOR PRODUCING THE SAME

(71) Applicants: Hideaki Asao, Kyotanabe-shi (JP); Shintaro Kubo, Kirishima-shi (JP); Shuji Nakazawa, Suwon-shi (KR); Yusuke Miyamichi, Hikone-shi (JP); Tatsuya Domoto, Higashiomi-shi (JP); Keizo Takeda, Omihachiman-shi (JP); Kazuki Yamada, Higashiomi-shi (JP); Kotaro Tanigawa, Higashiomi-shi (JP); Hiromitsu Ogawa, Higashiomi-shi (JP)

(72) Inventors: Hideaki Asao, Kyotanabe-shi (JP); Shintaro Kubo, Kirishima-shi (JP); Shuji Nakazawa, Suwon-shi (KR); Yusuke Miyamichi, Hikone-shi (JP); Tatsuya Domoto, Higashiomi-shi (JP); Keizo Takeda, Omihachiman-shi (JP); Kazuki Yamada, Higashiomi-shi (JP); Kotaro Tanigawa, Higashiomi-shi (JP); Hiromitsu Ogawa, Higashiomi-shi (JP)

(73) Assignee: KYOCERA CORPORATION, Kyoto-shi, Kyoto (JP)

(21) Appl. No.: 14/345,221

(22) PCT Filed: Aug. 17, 2012
(86) PCT No.: PCT/JP2012/070898

§ 371 Date: Mar. 14, 2014

(30) Foreign Application Priority Data
Sep. 16, 2011 (JP) 2011-202818
Nov. 21, 2011 (JP) 2011-253504

(51) Int. Cl. H01L 31/0749; H01L 31/18

(52) U.S. Cl. CPC H01L 31/0749; H01L 31/18
USPC 136/262; 438/95

(57) ABSTRACT

A photoelectric conversion device and a method for producing a photoelectric conversion device are disclosed. The photoelectric conversion device includes a light-absorbing layer. The light-absorbing layer contains a chalcopyrite-based compound, and has a peak intensity ratio I_{B}/I_{A} in a range of 3 to 9, where I_{A} represents a peak intensity of the peak formed by combining a peak of a (220) plane and a peak of a (204) plane in X-ray diffraction, and I_{B} represents a peak intensity of a (112) plane.

### TECHNICAL FIELD

The present invention relates to a photoelectric conversion device containing a chalcopyrite-based compound and a method for producing the same.

### BACKGROUND ART

A type of the photoelectric conversion devices used for photovoltaic power generation or the like includes a light absorbing layer containing a chalcopyrite-based compound having a high photo-absorption coefficient, such as CIGS. For example, Japanese Unexamined Patent Application Publication No. 8-330614 disclosed such a photoelectric conversion device. Chalcopyrite-based compound semiconductors have high photo-absorption coefficients and are suitable for reducing the thickness or increasing the area of photoelectric conversion devices. Accordingly, next-generation solar cells using these semiconductors are being developed.

Such a chalcopyrite-based photoelectric conversion device includes a plurality of photoelectric conversion cells that are arranged on a plane on a substrate made of glass or the like. Each of the photoelectric conversion cells includes an lower electrode layer such as a metal electrode, a light absorbing layer, a buffer layer, and a transparent conductive film (upper electrode layer), in that order, on the substrate. The plurality of photoelectric conversion cells are electrically connected in series in such a manner that the transparent conductive film of one of any two adjacent photoelectric conversion cells is connected to the lower electrode layer of the other with a connecting conductor.

The photoelectric conversion efficiency of photoelectric conversion devices containing a chalcopyrite-based compound is always required to be increased. The term photoelectric conversion efficiency refers to the percentage of solar light energy converted into electrical energy in a photoelectric conversion device. For example, a photoelectric conversion efficiency can be obtained by dividing the value of electrical energy output from a photoelectric conversion device by the value of solar light energy incident on the photoelectric conversion device and then multiplying the resulting value by 100.

### SUMMARY OF INVENTION

An object of the present invention is to increase the photoelectric conversion efficiency of a photoelectric conversion device.

A photoelectric conversion device according to an embodiment of the present invention is a photoelectric conversion device in which a light absorbing layer contains a chalcopyrite-based compound. The light absorbing layer has a peak intensity ratio I_{B}/I_{A} in the range of 3 to 9, wherein I_{A} represents a peak intensity of a peak formed by combining a peak of a (220) plane and the peak of a (204) plane in X-ray diffraction, and I_{B} represents a peak intensity of a (112) plane.

A method for producing a photoelectric conversion device according to an embodiment of the present invention includes the following process steps. A first step is the step of preparing a first coating film containing a metal element and a chalcogen element. A second step is the step of making a second coating film by heating the first coating film in an atmosphere containing water or oxygen. A third step is the step of converting the second coating film into the light absorbing layer having the abovementioned peak intensity ratio I_{B}/I_{A} in the range of 3 to 9 by heating the second coating film in a non-oxidizing atmosphere and subsequently in an atmosphere containing a chalcogen element.

According to the present invention, the photoelectric conversion efficiency of the photoelectric conversion device is increased.

### BRIEF DESCRIPTION OF DRAWINGS

FIG. 1 is a perspective view of a photoelectric conversion device according to an embodiment.

FIG. 2 is a cross-sectional view of the photoelectric conversion device shown in FIG. 1.

FIG. 3 is a graph showing the relationship between the X-ray diffraction peak intensity ratio and the short-circuit current density of light absorbing layers.

FIG. 4 is a fragmentary enlarged graph of the graph shown in FIG. 3.

FIG. 5 is a graph showing the relationship between the X-ray diffraction peak intensity ratio and the photoelectric conversion efficiency of light absorbing layers.

FIG. 6 is a fragmentary enlarged graph of the graph shown in FIG. 5.

### DESCRIPTION OF EMBODIMENTS

A photoelectric conversion device according to an embodiment of the present invention will be described in detail below with reference to the drawings.

### <Structure of Photoelectric Conversion Device>

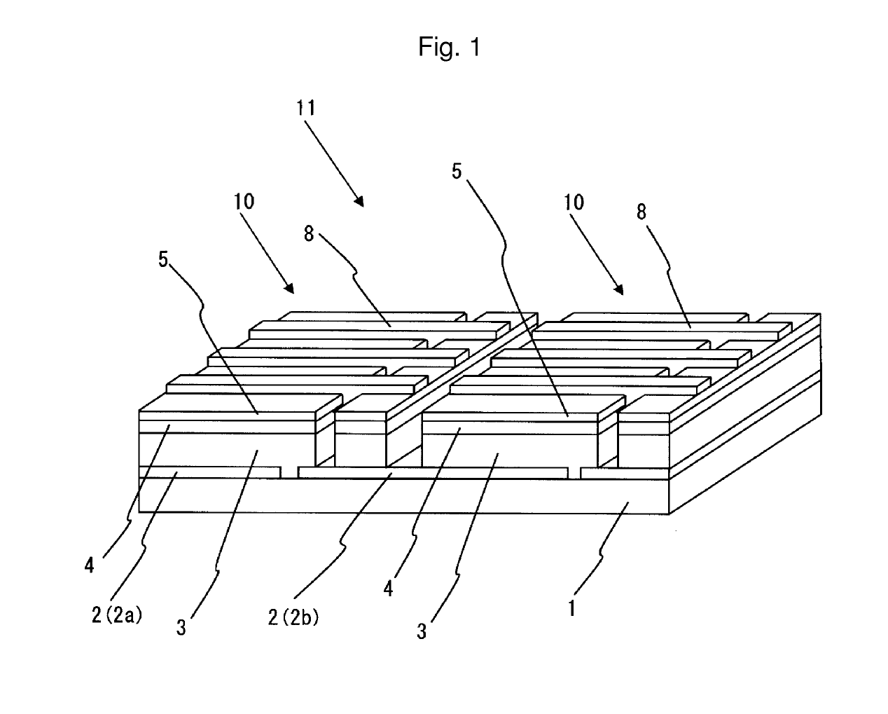

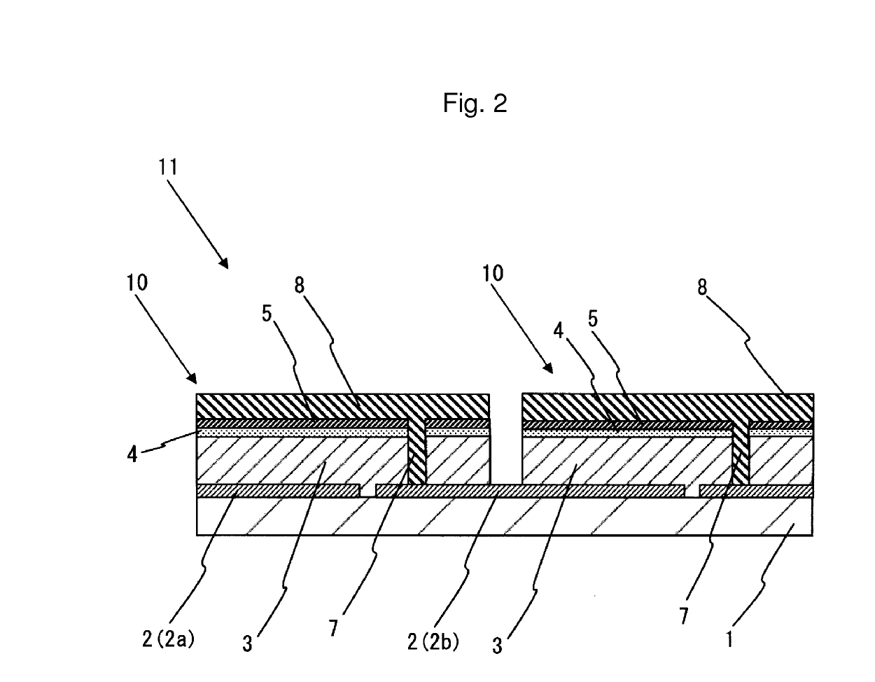

FIG. 1 is a perspective view of a photoelectric conversion device according to an embodiment of the present invention, and FIG. 2 is a cross-sectional view of the photoelectric conversion device. The photoelectric conversion device 11 includes a plurality of photoelectric conversion cells 10 arranged on a substrate 1 and are electrically connected. FIG. 1 illustrates only two of the photoelectric conversion cells 10 for the sake of convenience of illustration. However, in the photoelectric conversion device 11 in a practice, many photoelectric conversion cells 10 may be arranged on a plane (two-dimensionally) in the lateral direction of the figure.

In FIGS. 1 and 2, a plurality of lower electrode layers 2 are arranged on a plane on the substrate 1. A light absorbing layer (hereinafter may be referred to as first semiconductor layer 3), a second semiconductor layer 4, and an upper electrode layer 5 are disposed over an area from the lower electrode layer 2a of one of two adjacent lower electrode layers 2 to the lower electrode layer 2b of the other. Then, a connecting conductor 7 is formed above the lower electrode layer 2b to electrically connect the lower electrode layer 2b and the upper electrode layer 5. These components: the lower electrode layers 2, the first semiconductor layer 3, the second semiconductor layer 4, the upper electrode layer 5, and the connecting conductor 7 constitute a single photoelectric conversion cell 10. The lower electrode layer 2b connects the adjacent photoelectric conversion cells 10. This structure defines a photoelectric conversion device 11 in which any two adjacent photoelectric conversion cells 10 are connected in series.

In the photoelectric conversion device 11 of the present embodiment, light enters the first semiconductor layer 3 through the second semiconductor layer 4. However, the photoelectric conversion device 11 is not limited thereto and light may enter through the substrate 1. Also, the first semiconductor layer 3 acting as a light absorbing layer and the second semiconductor layer 4 may be reversed in such a manner that the second semiconductor layer 4 and the first semiconductor layer 3 are disposed in that order on the substrate 1.

The substrate 1 is intended to support the photoelectric conversion cells 10. The material of the substrate 1 may be, for example, glass, a ceramic, a resin, or a metal. A blue glass plate (soda lime glass) of about 1 to 3 mm in thickness may be used as the substrate 1.

The lower electrode layers 2 (lower electrode layers 2a and 2b) are electric conductors of Mo, Al, Ti, Au or the like disposed on the substrate 1. The lower electrode layers 2 are formed to a thickness of about 0.2 μm to 1 μm by a known thin film deposition method, such as sputtering or vacuum evaporation.

The first semiconductor layer 3 is a semiconductor layer containing a chalcopyrite-based compound and has a first-type conductivity. The first semiconductor layer 3 functions as a light absorbing layer, and has a thickness of, for example, about 1 μm to 3 μm. Chalcopyrite-based compounds are compounds having a chalcopyrite structure, and examples thereof include group I-III-VI compounds and group II-IV-V compounds.

Group I-III-VI compounds each contain a group I-B element (may be referred to as group 11 element), a group III-B element (may be referred to as group 13 element), and a group VI-B element (may be referred to as group 16 element). Exemplary group I-III-VI compounds include CuInSe₂ (copper indium diselenide or CIS), Cu(In, Ga)Se₂ (copper indium gallium diselenide or CIGS), and Cu(In, Ga)(Se, S)₂ (copper indium gallium diselenide disulfide or CIGSS). Alternatively, the first semiconductor layer 3 may be made of a multinary compound semiconductor film of copper indium gallium diselenide or the like including a thin copper indium gallium diselenide disulfide layer as the surface layer.

Group II-IV-V compounds each contain a group II-B element (may be referred to as group 12 element), a group IV-B element (may be referred to as group 14 element), and a group V-B element (may be referred to as group 15 element). Exemplary group II-IV-V compounds include CdSnP₂, CdSnSb₂, CdGeAs₂, CdGeP₂, CdSiAs₂, CdSiP₂, CdSiSb₂, ZnSnSb₂, ZnSnAs₂, ZnSnP₂, ZnGeAs₂, ZnGeP₂, ZnGeSb₂, ZnSiAs₂, ZnSiP₂, and ZnSiSb₂.

The first semiconductor layer 3 has a peak intensity ratio I_{B}/I_{A} in the range of 3 to 9. Here, I_{A} represents the X-ray diffraction peak intensity of the peak formed by combining the peak of a (220) plane and the peak of a (204) plane, and I_{g} represents the X-ray diffraction peak intensity of a (112) plane. This structure can increase the short-circuit current density (JSC) of the first semiconductor layer 3, consequently increasing the photoelectric conversion efficiency of the photoelectric conversion device 11.

The first semiconductor layer 3 may further contain elemental oxygen. The elemental oxygen can fill the defects in the first semiconductor layer 3 to reduce carrier recombination. The atomic concentration of the elemental oxygen in the first semiconductor layer 3 may be, for example, 2×10¹⁹ to 3×10²¹ atoms/cm³.

The second semiconductor layer 4 is a semiconductor layer having a second-type conductivity opposite to the first semiconductor layer 3. By electrically connecting the first semiconductor layer 3 and the second semiconductor layer 4, a photoelectric conversion layer is defined from which charges can be favorably extracted. For example, if the first semiconductor layer 3 is of p-type, the second semiconductor layer 4 is of n-type. Alternatively, the first semiconductor layer 3 may be of n-type, and the second semiconductor layer 4 may be of p-type. The first semiconductor layer 3 and the second semiconductor layer 4 may be separated by a buffer layer having a high resistance.

The second semiconductor layer 4 may be a layer formed by depositing a material different from the material of the first semiconductor layer 3 on the first semiconductor layer 3, or a layer modified from the first semiconductor layer 3 by doping the surface of the first semiconductor layer 3 with another element.

Examples of the material of the second semiconductor layer 4 include CdS, ZnS, ZnO, In₂S₃, In₂Se₃, In(OH, S), (Zn, In)(Se, OH), and (Zn, Mg)O. In this instance, the second semiconductor layer 4 is formed, for example, to a thickness of 10 to 200 nm by chemical bath deposition (CBD). In(OH, S) refers to a compound mainly containing In, OH, and S. (Zn, In)(Se, OH) refers to a compound mainly containing Zn, In, Se, and OH. (Zn, Mg)O refers to a compound mainly containing Zn, Mg, and O.

Furthermore, the second semiconductor layer 4 may be provided with an upper electrode layer 5 thereon, as shown in FIGS. 1 and 2. The upper electrode layer 5 has a lower resistivity than the second semiconductor layer 4 and allows charges generated in the first semiconductor layer 3 and the second semiconductor layer 4 to be easily extracted. From the viewpoint of increasing the photoelectric conversion efficiency, the upper electrode layer 5 may have a resistivity of less than 1 Ω·cm and a sheet resistance of 50 Ω/sq. or less.

The upper electrode layer 5 is a transparent conductive film made of, for example, ITO, ZnO or the like and having a thickness of 0.05 to 3 μm. Alternatively, the upper electrode layer 5 may be made of a semiconductor having the same type of conductivity as the second semiconductor layer 4 from the viewpoint of increasing the optical transparency and conductivity thereof. The upper electrode layer 5 can be formed by sputtering, vacuum evaporation, chemical vapor deposition (CVD), or the like.

Furthermore, the upper electrode layer 5 may be provided with a collector electrode 8 thereon, as shown in FIGS. 1 and 2. The collector electrode 8 is intended to favorably extract charges generated in the first semiconductor layer 3 and the second semiconductor layer 4. For example, the collector electrode 8 linearly extends from an end of the photoelectric conversion cell 10 across the connecting conductor 7, as shown in FIG. 1. Thus, each collector electrode 8 collects the current generated in the first semiconductor layer 3 and the fourth semiconductor layer 4 through the upper electrode layer 5, and the collected current is favorably conducted to the adjacent photoelectric conversion cell 10 through the corresponding connecting conductor 7.

The collector electrode 8 may have a width of 50 to 400 μm from the viewpoint of increasing light transmission to the first semiconductor layer 3 and having a good electrical conductivity. The collector electrodes 8 may have a plurality of branched portions.

The collector electrode 8 is formed by, for example, printing a pattern with a metal paste containing a metal powder, such as Ag powder, dispersed in a resin binder or the like, and then curing the pattern.

In FIGS. 1 and 2, each connecting conductor 7 fills a hole passing through the first semiconductor layer 3, the second semiconductor layer 4 and the upper electrode layer 5. The connecting conductor 7 can be made of a metal, a conductive paste or the like. Although the connecting conductor 7 shown in FIGS. 1 and 2 is formed by elongating the collector electrode 8, it is not limited thereto.

For example, the upper electrode layer 5 may be elongated.

### <Process for Forming Light Absorbing Layer (First Process)>

A process for forming the first semiconductor layer 3 to act as a light absorbing layer will now be described. First, the case in which the first semiconductor layer 3 contains a group I-III-VI compound is described. A raw material solution containing metal elements (a group I-B element and a group M-B element) and a chalcogen element is applied onto the substrate 1 having the first electrode layers 2 thereon so as to form a coating film with a spin coater or a die coater or by screen printing, dipping, or spraying, thus forming a first coating film containing the metal elements and the chalcogen element. Chalcogen elements are S, Se, and Te of the group VI-B elements.

The first coating film may include a plurality of layers formed by repeating the operation of forming the coating film using the above raw material solution. Alternatively, the plurality of layers may be formed by using raw material solutions having different compositions.

Subsequently, a second coating film is made by heating the first coating film in an atmosphere containing water or oxygen (this step of heating in an atmosphere containing water or oxygen is hereinafter referred to as first step). If the first coating film contains an organic constituent, the organic constituent may be thermally decomposed in the first step.

The atmospheric gas used in the first step may be a mixed gas containing at least either an inert gas or a reducing gas and to which water (vapor) or oxygen gas is mixed. The inert gas may be nitrogen or argon, and the reducing gas may be hydrogen. The water (vapor) or oxygen content of the atmospheric gas may be, for example, 10 to 1000 ppmv in terms of parts per million by volume. Particularly when it is 50 to 150 ppmv, the coating film is difficult to crack or peel. Consequently, the first semiconductor layer 3 is satisfactorily crystallized, and the photoelectric conversion efficiency of the photoelectric conversion device 11 is further increased. The temperature of the atmosphere of the first step may be, for example, 50 to 350° C. By heating the first coating film in an atmosphere containing water or oxygen, as described above, the metal elements (group I-B element and group III-B element) in the first coating film are oxidized to some extent.

Subsequently, the second coating film is heated at a temperature of, for example, 100 to 500° C. in a non-oxidizing atmosphere (this step of heating in a non-oxidizing atmosphere is hereinafter referred to as second step). The non-oxidizing atmosphere is an atmosphere of an inert gas such as nitrogen or argon, an atmosphere of a reducing gas such as hydrogen, or an atmosphere of a mixture of these gases. In the second step, the metal elements and the chalcogen element in the second coating film react with each other to grow metal chalcogenide grains. This reaction proceeds relatively gently because the metal chalcogenide grains contain, in part, metal oxides. Accordingly, growing metal chalcogenide grains are easily oriented in the same direction.

After the second step, the second coating film is further heated in an atmosphere containing a chalcogen element at a temperature of, for example, 300 to 600° C. to allow the chalcogenation reaction of the second coating film to proceed, thus converting the second coating film into a first semiconductor layer 3 having a polycrystalline structure (this step of heating in an atmosphere containing a chalcogen element is hereinafter referred to as third step). The atmosphere of the third step contains a chalcogen element in the form of, for example, sulfur vapor, selenium vapor, tellurium vapor, hydrogen sulfide, hydrogen selenide, or hydrogen telluride.

While the second coating film is heated in an atmosphere containing a chalcogen element, the elemental oxygen in the second coating film can be substituted with the chalcogen element so that the concentration of the elemental oxygen remaining in the first semiconductor layer 3 can be reduced to a desired level. For example, as the time of heating in the atmosphere containing a chalcogen element is increased, or as the heating temperature is increased, the concentration of the elemental oxygen remaining in the first semiconductor layer 3 tends to decrease.

From the viewpoint of increasing the degree of the orientation of growing metal chalcogenide grains, the atmosphere of the third step may be such that it contains sulfur vapor, selenium vapor or tellurium vapor in the initial stage and is then replaced with an atmosphere containing a hydrogen chalcogenide, such as hydrogen sulfide, hydrogen selenide, or hydrogen telluride. In such an atmosphere, the chalcogen vapor allows the chalcogenation of the second coating film to proceed relatively gently, maintaining the orientation of the metal chalcogenide grains, and then, highly active hydrogen chalcogenide promotes the chalcogenation. Consequently, the degree of orientation and the crystallinity of the first semiconductor layer 3 to be produced can be increased.

Through the first to third steps performed as described above, the first semiconductor layer 3 can maintain a state where grains are aligned to some extent and have a peak intensity ratio I_{B}/I_{A} in the range of 3 to 9. Here, I_{A} represents the X-ray diffraction peak intensity of the peak formed by combining the peak of a (220) plane and the peak of a (204) plane, and I_{B} represents the X-ray diffraction peak intensity of a (112) plane.

### <Another Process for Forming Light Absorbing Layer (Second Process)>

A process other than the first process enables the light absorbing layer to have an appropriate orientation for a peak intensity ratio I_{B}/I_{A} in the range of 3 to 9.

For example, a raw material solution containing a single-source complex that is a single organic complex whose molecule contains a group I-B element, a group III-B element and a chalcogen element (for an example of a single-source complex, see U.S. Pat. No. 6,992,202) is applied onto the substrate 1 having the first electrode layers 2 so as to form a coating film with a spin coater or a die coater or by screen printing, dipping, or spraying, thus forming the first coating film. The first coating film may be a multilayer composite including a plurality of layers having different compositions.

In this process, a compound having an asymmetrical molecular structure in terms of the steric bulk of ligands is used as the single-source complex. In the asymmetrical molecular structure, bulky ligands are coordinated at one end of the structure and non-bulky ligands are coordinated at the other end. The use of such a single-source complex having an asymmetrical structure in terms of steric bulk further increases the degree of orientation in the first coating film. An example of the single-source complex having such an asymmetrical structure in terms of steric bulk may be a compound expressed by structural formula 1. In structural formula 1, Ph represents a phenyl group, Et represents an ethyl group, MI represents a group I-B element, and MIII represents a group III-B element.

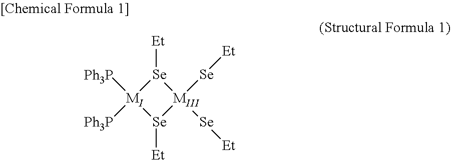

After the formation of the highly oriented first coating film, the first to third steps are performed as in the first process, so that the first semiconductor layer 3 has a peak intensity ratio I_{B}/I_{A} in the range of 3 to 9.

### Examples

The method for producing a semiconductor layer according to the present embodiment was evaluated as described below. In the following examples, CIGS was used as the semiconductor layers.

### <Preparation of Raw Material Solution>

First, a raw material solution was prepared as described below.

[a1] In 100 mL of acetonitrile were dissolved 10 millimoles (mmol) of Cu(CH₃CN)₄.PF₆ and 20 mmol of P(C₆H₅)₃. The resulting solution was stirred at room temperature (25° C.) for 5 hours to yield a first complex solution.

[a2] In 300 mL of methanol were dissolved 40 mmol of sodium methoxide (NaOCH₃) and 40 mmol of phenylselenol (HSeC₆H₅). After dissolving 6 mmol of InCl₃ and 4 mmol of GaCl₃ in this solution, the resulting solution was stirred at room temperature for 5 hours to yield a second complex solution.

[a3] The second complex solution prepared in step [a2] was dropped into the first complex solution prepared in step [a1] to produce a white precipitate (sediment). The precipitate contains a mixture of single-source complexes expressed by structural formulas 2 and 3. Each molecule of the complexes in the mixture of single-source complexes contains Cu, Ga and Se, or Cu, In and Se. Here, Ph in structural formulas 2 and 3 represents a phenyl group.

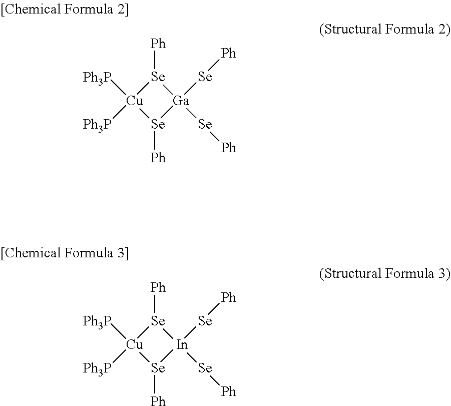

[a4] An organic solvent pyridine was added to the precipitate containing single-source complexes obtained in step [a3] to prepare a raw material solution.

### <Formation of First Semiconductor Layer (Sample 1)>

Subsequently, a structure was prepared in which a lower electrode layer containing Mo was formed on the surface of a glass substrate. Then, the raw material solution was applied onto the lower electrode layer by a blade method in a nitrogen gas atmosphere to form a first coating film.

The first coating film was heated at 300° C. for 10 minutes in a nitrogen atmosphere containing 100 ppmv of water to remove the organic solvent from the first coating film, thus yielding a second coating film.

Subsequently, the second coating film was heated from 25° C. to 400° C. at 30 minutes in a hydrogen gas atmosphere, and then Se vapor was added to a concentration of 5 ppmv to the hydrogen gas atmosphere, followed by further heating at 500° C. for one hour. Thus a first semiconductor layer of sample 1 mainly containing CIGS was completed.

### <Formation of First Semiconductor Layer (Sample 2)>

The raw material solution was applied onto a lower electrode layer containing Mo by a blade method in the same manner as in the formation of the first semiconductor layer of sample 1, thus forming a first coating film.

The first coating film was heated at 500° C. for 2 hours in a hydrogen gas atmosphere containing 5 ppmv of Se vapor. Thus a first semiconductor layer of sample 2 mainly containing CIGS was formed.

### <Formation of First Semiconductor Layer (Sample 3)>

A structure was prepared in which a lower electrode layer containing Mo was formed on the surface of a glass substrate. Then, a first semiconductor layer of sample 3 mainly containing CIGS was formed by evaporating Cu, In, Ga and Se onto the lower electrode.

### <Formation of First Semiconductor Layer (Sample 4)>

For forming a first coating film, the following second raw material solution was used instead of the above-described raw material solution. The second raw material solution was prepared as described below.

[b1] In 100 mL of acetonitrile were dissolved 10 millimoles (mmol) of Cu(CH₃CN)₄.PF₆ and 20 mmol of P(C₆H₅)₃. The resulting solution was stirred at room temperature (25° C.) for 5 hours to yield a third complex solution.

[b2] In 300 mL of methanol were dissolved 40 mmol of sodium methoxide (NaOCH₃) and 40 mmol of ethaneselenol (HSeC₂H₅). After dissolving 6 mmol of InCl₃ and 4 mmol of GaCl₃ in this solution, the resulting solution was stirred at room temperature for 5 hours to yield a fourth complex solution.

[b3] The fourth complex solution prepared in step [b2] was dropped into the third complex solution prepared in step [b1] to produce a white precipitate (sediment). The precipitate contains a mixture of single-source complexes having an asymmetrical structure in terms of steric bulk, expressed by structural formulas 4 and 5. In structural formulas 4 and 5, Ph represents a phenyl group, and Et represents an ethyl group.

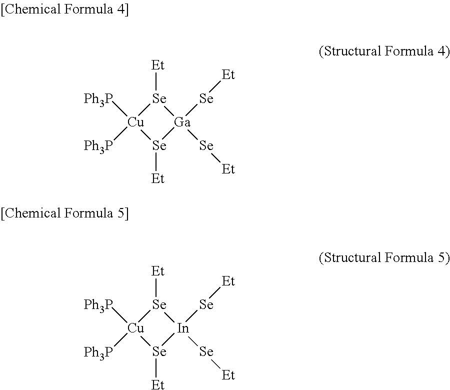

Subsequently, the second raw material solution was applied onto a lower electrode layer containing Mo by a blade method to form a first coating film.

The first coating film was heated at 300° C. for 10 minutes in a nitrogen atmosphere containing 100 ppmv of water to remove the organic solvent from the first coating film, thus yielding a second coating film.

Subsequently, the second coating film was heated from 25° C. to 400° C. at 30 minutes in a hydrogen gas atmosphere, and then Se vapor was added to a concentration of 5 ppmv to the hydrogen gas atmosphere, followed by heating at 500° C. for one hour. Thus a first semiconductor layer of sample 4 mainly containing CIGS was completed.

The resulting first semiconductor layers of samples 1 to 4 were subjected to X-ray diffraction measurement. For each of samples 1 to 4, the peak intensity ratio I_{B}/I_{A} was obtained, where I_{A} represents the X-ray diffraction peak intensity of the peak formed by combining the peak of a (220) plane and the peak of a (204) plane, and I_{B} represents the X-ray diffraction peak intensity of a (112) plane.

### <Production of Photoelectric Conversion Device>

A second semiconductor layer and an upper electrode layer were formed in that order on each of the first semiconductor layers of samples 1 to 4 formed as described above, thus producing photoelectric conversion devices.

More specifically, a substrate including the first semiconductor layer was immersed in a solution prepared by dissolving cadmium acetate and thiourea in ammonia water. Thus, a 50 nm thick second semiconductor layer containing CdS was formed on the first semiconductor layer. Furthermore, an upper electrode layer containing Al-doped zinc oxide was formed on the second semiconductor layer by sputtering.

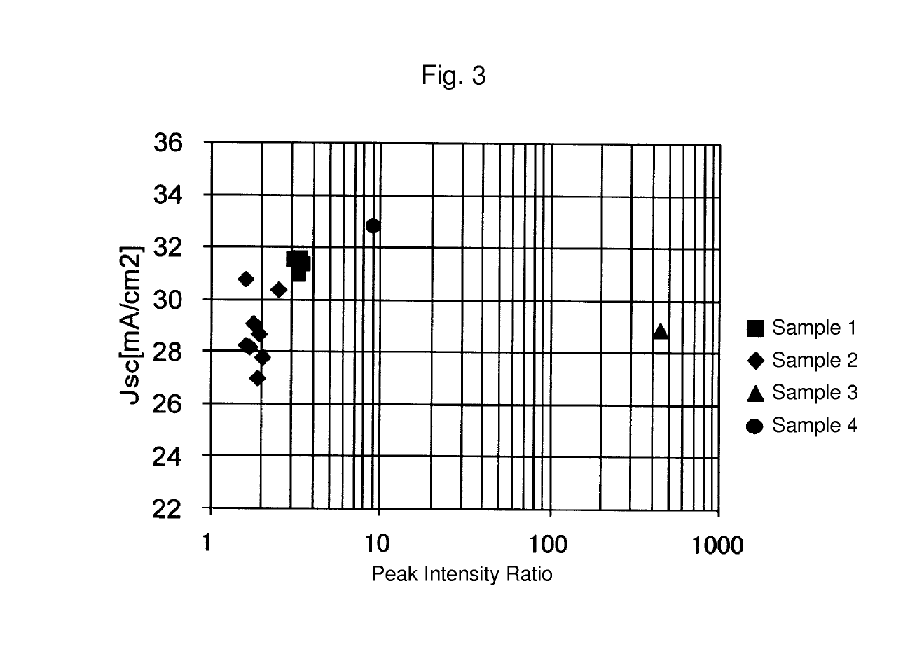

The resulting photoelectric conversion devices were subjected to measurements for short-circuit current density and photoelectric conversion efficiency, using a fixed-light solar simulator. The measurements were performed under the conditions in which the light radiation intensity at the light-receiving surface of the photoelectric conversion device was 100 mW/cm² and the air mass (AM) was 1.5. The results are shown in FIGS. 3 to 6.

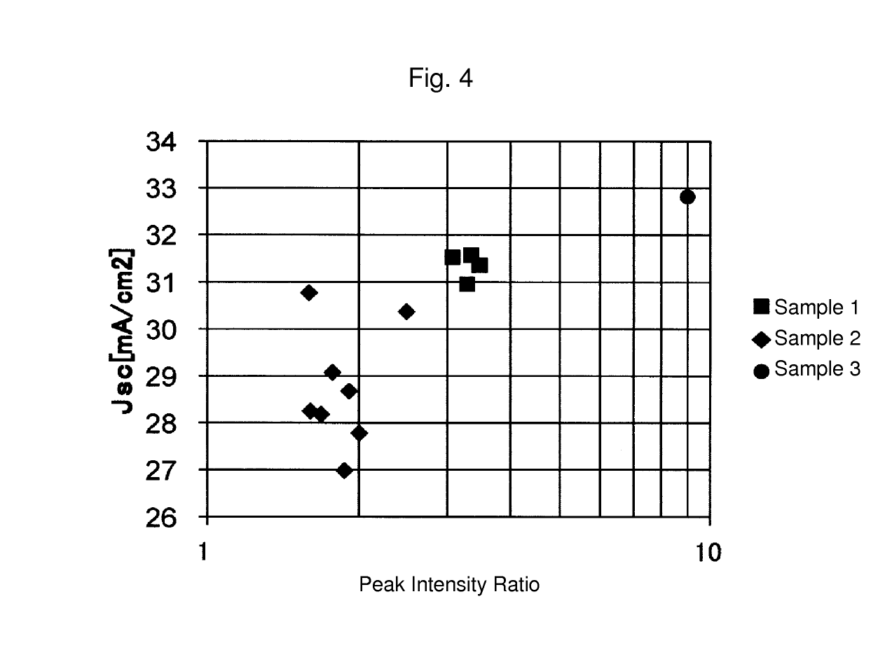

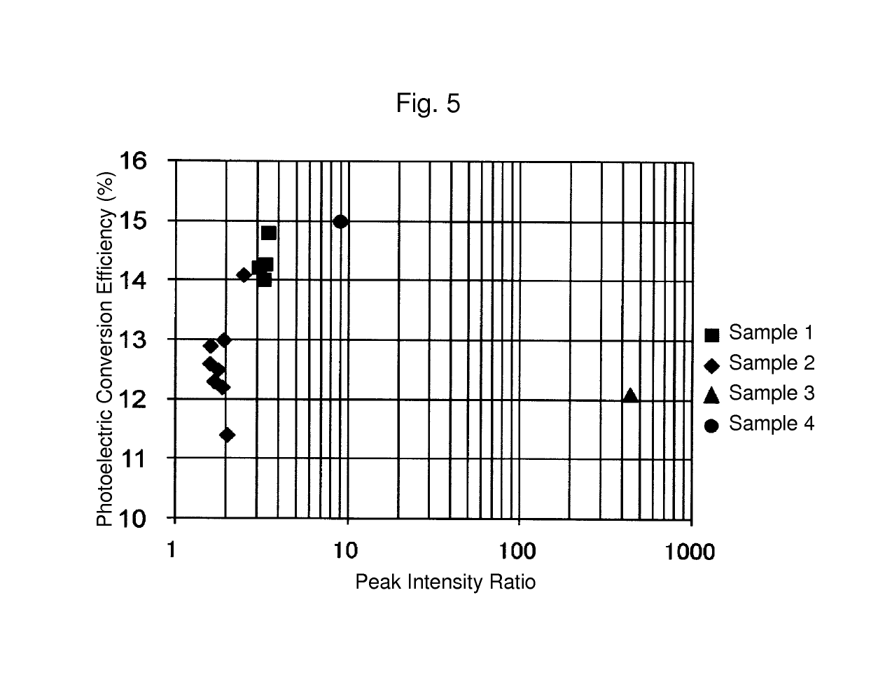

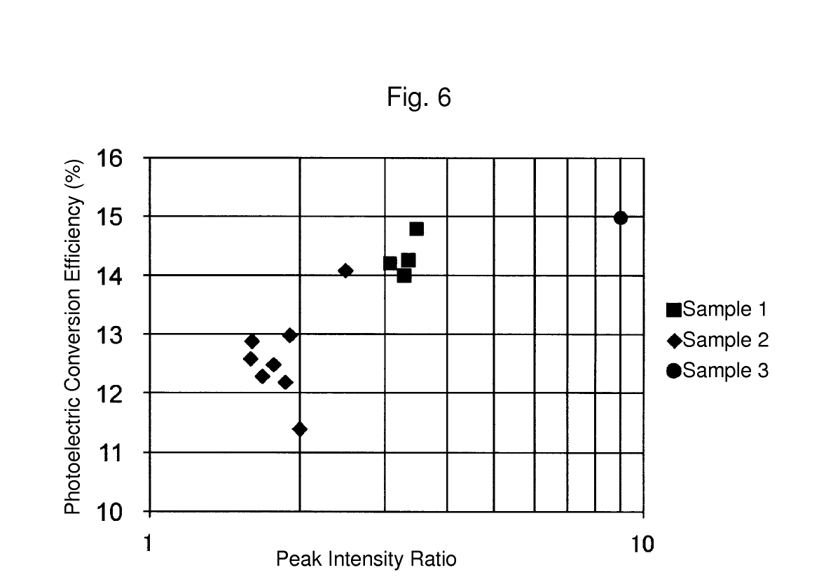

FIG. 3 shows the relationship between the peak intensity ratio I_{B}/I_{A} and the short-circuit current density JSC of samples 1 to 4, and FIG. 4 shows an enlargement of FIG. 3. FIG. 5 shows the relationship between the peak intensity ratio I_{B}/I_{A} and the photoelectric conversion efficiency of samples 1 to 4, and FIG. 6 shows an enlargement of FIG. 5.

These results show that samples 1 and 4 having peak intensity ratios I_{B}/I_{A} in the range of 3 to 9 exhibited higher short-circuit current densities and photoelectric conversion efficiencies than samples 2 and 3. In each graph, the results of some of the sample numbers include a plurality of data. These are data of a plurality of photoelectric conversion devices produced in the same production process.

The present invention is not limited to the disclosed embodiment, and various modifications may be made without departing from the spirit of the invention.

### REFERENCE SIGNS LIST

1: substrate
2, 2a, 2b: lower electrode layer
3: first semiconductor layer
4: second semiconductor layer
5: upper electrode layer
7: connecting conductor
8: collector electrode
10: photoelectric conversion cell
11: photoelectric conversion device

1. A photoelectric conversion device, comprising light absorbing layer,
wherein the light absorbing layer contains a chalcopyrite-based compound, and has a peak intensity ratio I_{B}/I_{A} in a range of 3 to 9, wherein I_{A} represents an X-ray diffraction peak intensity of a peak formed by combining a peak of a (220) plane and a peak of a (204) plane, and I_{B} represents an X-ray diffraction peak intensity of a (112) plane.

2. The photoelectric conversion device according to claim 1, wherein the chalcopyrite-based compound comprises a group I-III-VI compound.

3. The photoelectric conversion device according to claim 2, wherein the group I-III-VI compound contains copper as a group I-B element, indium and gallium as group III-B elements, and selenium as a group VI-B element.

4. The photoelectric conversion device according to claim 2, wherein the chalcopyrite-based compound further contains elemental oxygen.

5. A method for producing a photoelectric conversion device, the method comprising:
preparing a first coating film containing a metal element and a chalcogen element;
making a second coating film by heating the first coating film in an atmosphere containing water or oxygen; and
converting the second coating film into the light absorbing layer of claim 1 by heating the second coating film in a non-oxidizing atmosphere and subsequently heating the second coating film in an atmosphere containing a chalcogen element.

6. The method for producing a photoelectric conversion device according to claim 5, wherein a group I-B element and a group III-B element are used as the metal element.

7. The method for producing a photoelectric conversion device according to claim 5, wherein an atmosphere containing a chalcogen vapor and subsequently an atmosphere containing a hydrogen chalcogenide are used as the atmosphere containing a chalcogen element.
